(19) United States
(12) Patent Application Publication
(10) Pub. No.: US 2019/0285982 A1
(43) Pub. Date: Sep. 19, 2019

(54) MOLD, IMPRINT APPARATUS, AND METHOD OF MANUFACTURING ARTICLE

(71) Applicant: CANON KABUSHIKI KAISHA, Tokyo (JP)

(72) Inventor: Yoshihiro Shiode, Utsunomiya-shi (JP)

(21) Appl. No.: 16/298,018

(22) Filed: Mar. 11, 2019

(30) Foreign Application Priority Data
Mar. 13, 2018 (JP) 2018-045925

(51) Int. Cl. G03F 7/00; B29C 59/00; B29C 59/02; B29C 43/56

(52) U.S. Cl. CPC G03F 7/0002; B29C 43/56; B29C 59/022; B29C 59/002

(57) ABSTRACT

The present invention provides a mold having a concave-convex pattern, the pattern being transferred onto an imprint material on a substrate by an imprint apparatus, the mold comprising: a first surface having a pattern portion on which the pattern; and a second surface located on an opposite side to the first surface, wherein a concave portion that does not penetrate to the second surface is provided in the first surface so as to be spaced apart from the pattern portion.

### BACKGROUND OF THE INVENTION

### Field of the Invention

The present invention relates to a mold used for an imprint process, an imprint apparatus for forming a pattern on an imprint material onto a substrate using a mold, and a method of manufacturing an article.

### Description of the Related Art

An imprint apparatus for forming a pattern on an imprint material onto a substrate by using a mold on which a concave-convex pattern is formed has attracted attention as one type of mass-production lithography apparatus for semiconductor devices and the like. The imprint apparatus can form a pattern on an imprint material onto a substrate by curing the imprint material while the imprint material on the substrate is in contact with a mold and separating the mold from the cured imprint material. The process of forming a pattern on an imprint material onto a substrate by using a mold in this manner is generally called an imprint process.

In the imprint apparatus, in a contact process of bringing an imprint material on a substrate into contact with a mold, a pattern concave portion of the mold may not be fully filled with the imprint material to leave air bubbles between the mold and the imprint material. In this case, a pattern transfer failure (defect) onto the substrate can occur in a portion in which air bubbles are left. For this reason, in a contact process, the space between the mold and the substrate is preferably filled with a gas (to be sometimes referred to as a “filling promotion gas” hereinafter) for promoting the filling of the concave-convex pattern of the mold with the imprint material.

Japanese Patent No. 5828626 has proposed a technique of supplying a filling promotion gas to a moving path for the movement of a substrate from below a dispenser for dispensing an imprint material onto a substrate to below the mold. This moves a filling promotion gas to below the mold together with the substrate and makes the filling promotion gas efficiently flow into a narrow space between the mold and the substrate. Japanese Patent No. 5745532 has proposed a technique of forming a through hole in a mold and supplying a filling promotion gas into the space between the mold and a substrate via the through hole.

Some imprint apparatus uses a method of improving throughput by supplying an imprint material to each of a plurality of shot regions on a substrate and then performing an imprint process for each of the plurality of shot regions to which the imprint material has been supplied. In such a method, as disclosed in Japanese Patent No. 5828626, no filling promotion gas can be supplied to a moving path at the time of movement of a substrate from below a dispenser to below a mold, and it can be difficult to efficiently supply a filling promotion gas to the space between the mold and the substrate. In addition, in providing a through hole in a mold as disclosed in Japanese Patent No. 5745532, it is difficult to clean the through hole as well as performing a polishing process inside the through hole. As a consequence, foreign substances (particle) can be easily generated from the through hole.

### SUMMARY OF THE INVENTION

The present invention provides a technique advantageous in reducing transfer failures of patterns onto substrates.

According to one aspect of the present invention, there is provided a mold having a concave-convex pattern, the pattern being transferred onto an imprint material on a substrate by an imprint apparatus, the mold comprising: a first surface having a pattern portion on which the pattern; and a second surface located on an opposite side to the first surface, wherein a concave portion that does not penetrate to the second surface is provided in the first surface so as to be spaced apart from the pattern portion.

Further features of the present invention will become apparent from the following description of exemplary embodiments with reference to the attached drawings.

### BRIEF DESCRIPTION OF THE DRAWINGS

FIG. 1 is a schematic view showing the arrangement of an imprint apparatus;

FIG. 2 is a view showing a typical example of the arrangement of a mold;

FIG. 3 is a flowchart showing an imprint process in the imprint apparatus;

FIGS. 4A to 4E are views for explaining an imprint process;

FIGS. 5A to 5D are views showing an example of the arrangement of a mold according to the first embodiment;

FIGS. 6A to 6D are views showing an example of the arrangement of a mold according to the first embodiment;

FIG. 7 is a view showing a specific example of the dimensions of a mold;

FIGS. 8A to 8D are views showing an example of the arrangement of a mold according to the second embodiment;

FIGS. 9A and 9B are views showing the positional relationship between a mold and a substrate;

FIGS. 10A to 10D are views showing an example of the arrangement of a mold according to the third embodiment;

FIGS. 11A to 11D are views showing an example of the arrangement of a mold according to the third embodiment;

FIGS. 12A to 12D are views showing an example of the arrangement of a mold according to the third embodiment; and

FIGS. 13A to 13F are views showing a method of manufacturing an article.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given. Assume that in the following description, two different (orthogonal) directions in a plane parallel to a surface of a substrate are defined as an X direction and a Y direction, respectively, and a direction perpendicular to the surface of the substrate is defined as a Z direction.

<First Embodiment>

An imprint apparatus 100 according to the first embodiment of the present invention will be described. The imprint apparatus is an apparatus for forming a pattern of a curable material onto which a concave-convex pattern on a mold is transferred by bringing an imprint material supplied onto a substrate into contact with the mold and applying energy for curing the imprint material. The imprint apparatus 100 is used to manufacture a semiconductor device and the like and performs an imprint process of transferring a concave-convex pattern onto an imprint material R supplied onto a shot region of a substrate W by using a mold M, on which the pattern is formed. For example, the imprint apparatus 100 cures the imprint material R while the mold M on which the pattern is formed is in contact with the imprint material R on the substrate. The imprint apparatus 100 can then form a pattern on the imprint material R by increasing the spacing between the mold M and the substrate W and separating (releasing) the mold M from the cured imprint material R.

Methods of curing an imprint material include a thermal cycle method using heat and a photo-curing method using light. This embodiment will exemplify a case using the photo-curing method. The photo-curing method is a method of curing an imprint material by supplying an uncured ultraviolet curable resin as the imprint material onto a substrate and irradiating the imprint material with light (ultraviolet light) while a mold 1 is in contact with the imprint material.

As the imprint material, a curable composition (to be also referred to as a resin in an uncured state) to be cured by energy for curing is used. As the energy for curing, an electromagnetic wave, heat, or the like is used. The electromagnetic wave is, for example, light such as infrared rays, visible light, or UV rays whose wavelength is selected from the range of 10 nm to 1 mm.

The curable composition is a composition cured by light irradiation or heating. A photo-curable composition cured by light contains at least a polymerizable compound and a photopolymerization initiator, and may contain a nonpolymerizable compound or a solvent as needed. The nonpolymerizable compound is at least one material selected from the group consisting of a sensitizer, a hydrogen donor, an internal mold release agent, a surfactant, an antioxidant, and a polymer component.

The imprint material is applied in a film shape onto the substrate by a spin coater or a slit coater. Alternatively, the imprint material may be applied, onto the substrate, in a droplet shape or in an island or film shape formed by connecting a plurality of droplets using a liquid injection head. The viscosity (viscosity at 25° C.) of the imprint material is, for example, 1 mPa.s to 100 mPa.s.

[Apparatus Arrangement]

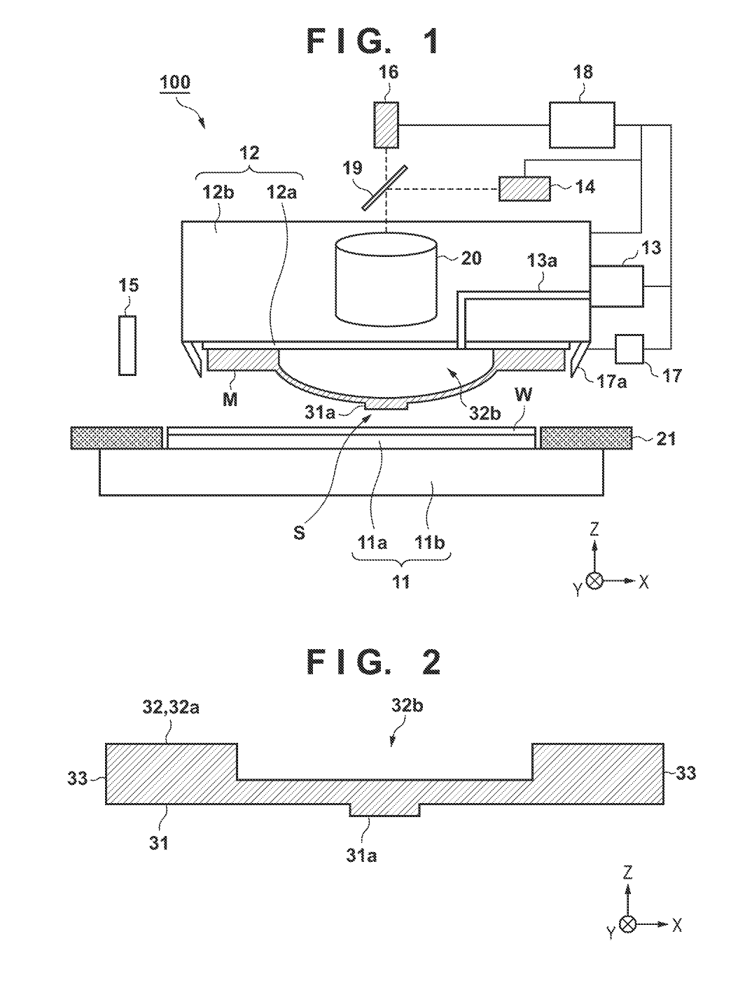

The arrangement of the imprint apparatus 100 according to the first embodiment will be described next with reference to FIG. 1. FIG. 1 is a schematic view showing the arrangement of the imprint apparatus 100 according to this embodiment. The imprint apparatus 100 can include a substrate stage 11, an imprint head 12, a deformation unit 13, a curing unit 14, a dispenser 15, an image capturing unit 16, a supply unit 17, and a control unit 18. The control unit 18 is formed from, for example, a computer including a CPU and a memory, and controls an imprint process (controls each unit of the imprint apparatus 100).

The substrate stage 11 includes, for example, a substrate holding unit 11a and a substrate driving unit 11b, and is configured to be movable while holding the substrate W. The substrate holding unit 11a holds the substrate W with, for example, a vacuum suction force or electrostatic force. The substrate driving unit 11b mechanically holds the substrate holding unit 11a and drives the substrate holding unit 11a (substrate W) in the X and Y directions. In addition, the substrate driving unit 11b may be configured to change the position of the substrate W in the Z direction, the tilt of the substrate W relative to the X-Y plane, and the rotation of the X-Y plane.

In this case, glass, ceramic, a metal, a semiconductor, a resin, or the like may be used for the substrate W, and a member made of a material different from that of the substrate may be formed on its surface, as needed. Specific examples of the substrate W include a silicon wafer, compound semiconductor wafer, and quartz glass. An adhesive layer may be provided before the addition of an imprint material to improve the adhesiveness between the imprint material and the substrate, as needed.

The imprint head 12 can include a mold holding unit 12a that holds the mold M with, for example, a vacuum suction force or electrostatic force and a mold driving unit 12b configured to change the position and tilt of the mold holding unit 12a (mold 1) in the Z direction. In addition, the mold driving unit 12b may be configured to adjust the positions of the mold M in the X and Y directions.

The arrangement of the mold M held by the imprint head 12 will be described below. FIG. 2 is a schematic view showing a typical example of the arrangement of the mold M. The mold M is generally formed from a material that can transmit ultraviolet light, such as quartz, and includes a first surface 31 as a substrate-side surface and a second surface 32 located on the opposite side to the first surface 31.

The first surface 31 is provided with a pattern portion 31a having a concave-convex pattern to be transferred as a device pattern onto an imprint material on a substrate. The pattern portion 31a is formed from, for example, a stepped portion (that is, a mesa shape) with a size of above several 10 μm, which protrudes from the first surface 31 toward the substrate. Although the size of the pattern portion 31a differs depending on a device pattern to be transferred onto a substrate, the size is generally set to 33 mm×26 mm.

The second surface 32 includes a held portion 32a that comes into contact with the holding surface of the mold holding unit 12a and is held by the mold holding unit 12a and a cavity 32b (second concave portion) provided on the opposite side to the pattern portion 31a of the first surface 31 and its surroundings. The cavity 32b is provided to easily deform the first surface 31 into a convex shape such that the central portion of the pattern portion 31a protrudes toward the substrate W when, for example, the mold M comes into contact with the imprint material R on the substrate. The cavity 32b becomes an almost sealed space when being held by the mold holding unit 12a, and communicates with the deformation unit 13 (to be described later) via a pipe 13a.

The deformation unit 13 adjusts the internal pressure of the cavity 32b by controlling the supply of compressed air into the cavity 32b of the mold M held by the imprint head 12, and deforms the first surface 31 of the mold M into a convex shape. The deformation unit 13 can reduce air bubbles left between the mold M and the imprint material R by controlling the deformation of the first surface 31 so as to gradually increase the contact area between the mold M and the imprint material R on the substrate in a process of bringing the mold M into contact with the imprint material R.

The curing unit 14 irradiates a substrate W with light (for example, ultraviolet light) for curing the imprint material R via the mold M in a process of curing the imprint material R on the substrate. In this embodiment, light emitted from the curing unit 14 is reflected by a beam splitter 19 (for example, a dichroic mirror) and irradiates the substrate W via a relay optical system 20 and the mold M. The dispenser 15 dispenses (applies) the imprint material R onto the substrate. As described above, the imprint apparatus 100 according to this embodiment can dispense an ultraviolet curable resin having a property of being cured by irradiation with ultraviolet light as the imprint material R from the dispenser 15 onto the substrate.

The image capturing unit 16 captures an image of the pattern portion 31a of the mold M via the beam splitter 19 and the relay optical system 20. For example, the image capturing unit 16 captures an image of the pattern portion 31a at each of a plurality of timings while the contact area between the mold M and the imprint material R is increased. Each image obtained by the image capturing unit 16 in this manner has interference fringes caused by contact between the mold M and the substrate W, and hence it is possible to observe, based on each image, the manner of how the contact area between the pattern portion 31a and the imprint material R increases. In addition, the imprint apparatus 100 may be provided with, for example, a detector (alignment scope) that detects alignment marks on the mold M and the substrate W to align the mold M and the substrate W

The supply unit 17 supplies a gas (filling promotion gas) for promoting the filling of the concave-convex pattern of the mold M with the imprint material R to between the mold M and the substrate W. The supply unit 17 has a blowing-out port 17a (supply port or nozzle) for blowing out a filling promotion gas from a side of the mold M to between the mold M and the substrate W, and supplies a filling promotion gas via the blowing-out port 17a. The blowing-out port 17a can be arranged near, for example, the mold M held by the imprint head 12. In the case shown in FIG. 1, two blowing-out ports 17a are arranged on a side of the mold M in the X direction. However, this is not exhaustive. For example, two blowing-out ports 17a may be further provided on a side of the mold M in the Y direction, or only one blowing-out port 17a may be provided. In addition, the blowing-out port 17a is not limited to a structure for blowing out a filling promotion gas to between the mold M and the substrate W. For example, the blowing-out port 17a may be configured to blow out a filling promotion gas toward a side surface of the mold M.

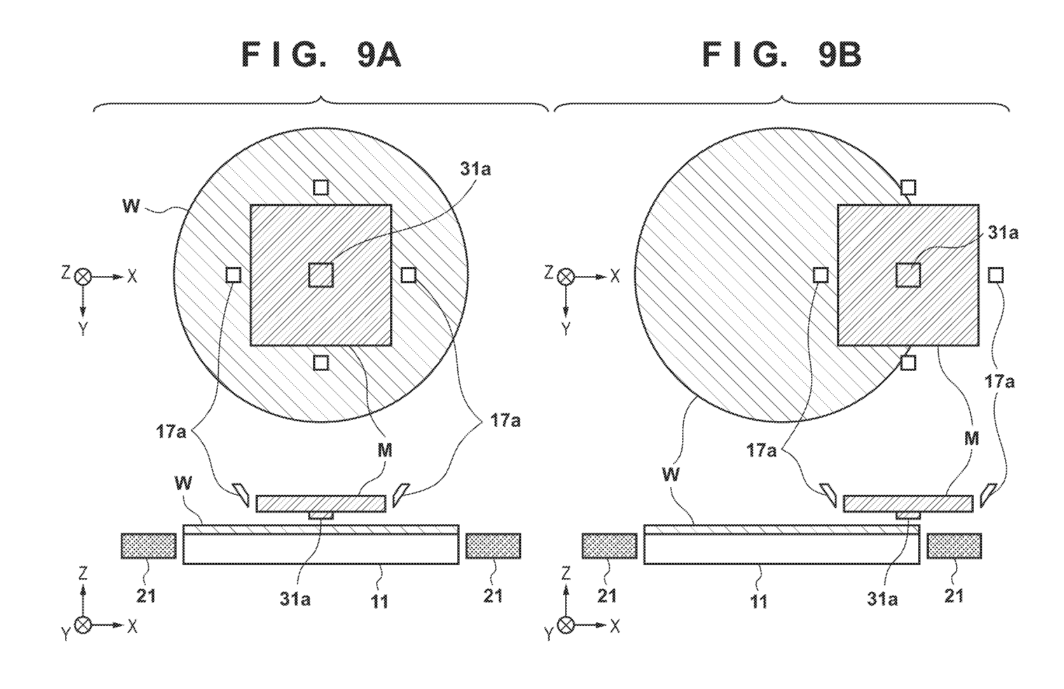

In this case, examples of a filling promotion gas that can be used include a gas having a small molecular weight and high permeability with respect to the mold M, such as helium gas, and a condensable gas that liquefies when the mold M comes into contact with the imprint material R on the substrate, such as PFP (pentafluoropropane) gas. As shown in FIG. 9B, when the imprint apparatus 100 performs an imprint process for a shot region arranged on a peripheral edge portion of the substrate W, a filling promotion gas can be made to flow from a space S between the pattern portion 31a of the mold M and the substrate W. For this reason, in the imprint apparatus 100 according to this embodiment a flush face plate 21 is provided on the substrate stage 11. The flush face plate 21 is arranged around the substrate W such that the upper surface of the flush face plate 21 is almost flush with the upper surface of the substrate W. The flush face plate 21 is preferably arranged around the substrate W such that the upper surface of the flush face plate 21 is lower than the upper surface of the substrate W and higher than the substrate holding surface of the substrate stage 11.

[Imprint Process]

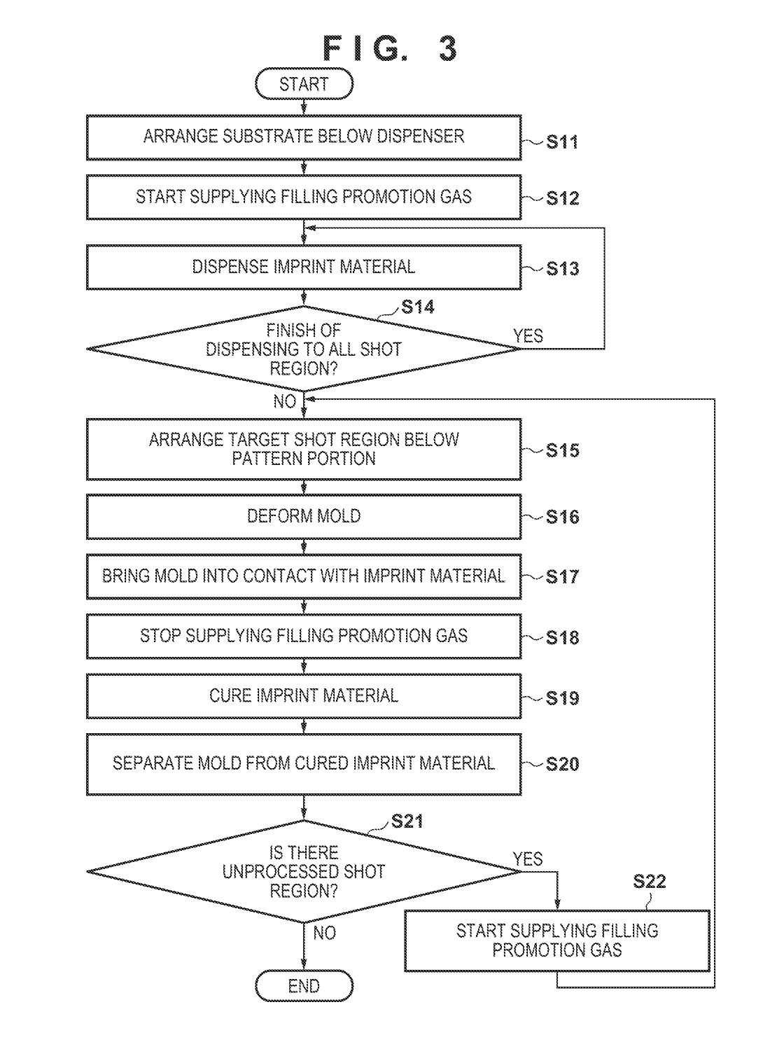

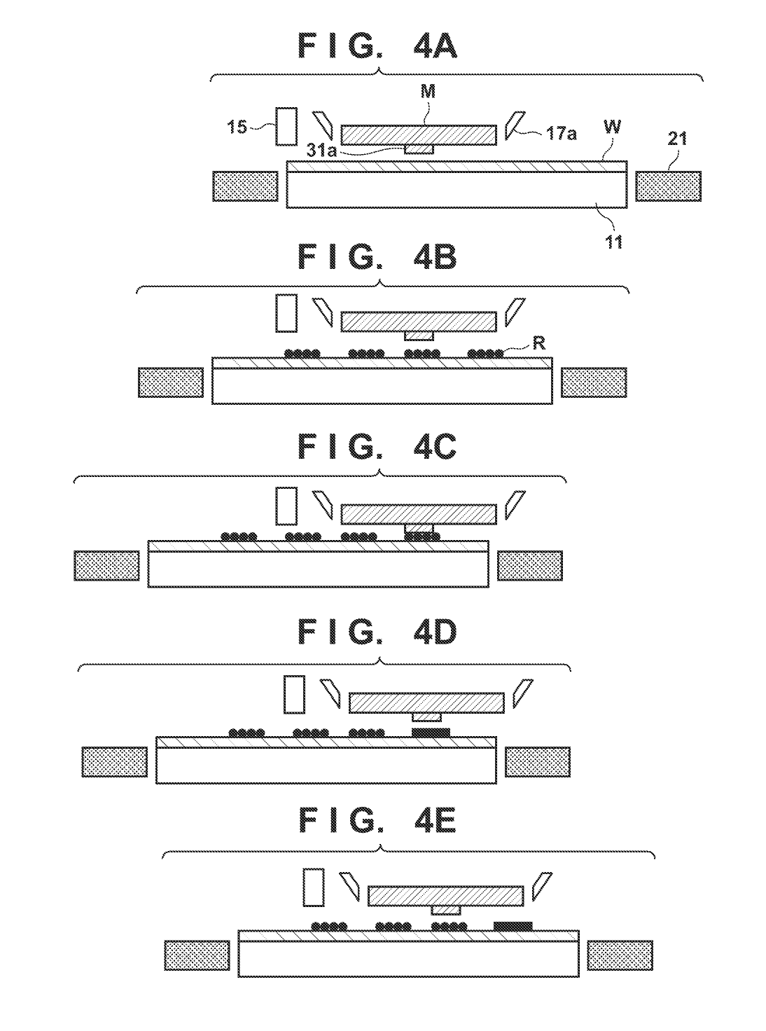

An imprint process performed by the imprint apparatus 100 according to this embodiment will be described next. The imprint apparatus 100 according to the embodiment can be configured to sequentially dispense the imprint material R from the dispenser 15 to each of a plurality of shot regions on the substrate W and then sequentially perform an imprint process for each of the plurality of shot regions. FIG. 3 is a flowchart showing an imprint process performed by the imprint apparatus 100 according to the embodiment. The control unit 18 can control each step in the flowchart shown in FIG. 3. FIGS. 4A to 4E are views for explaining an imprint process. For the sake of easy understanding, FIGS. 4A to 4E each show only the mold M, the substrate W, the substrate stage 11, the flush face plate 21, the dispenser 15, and the supply unit 17 (blowing-out port 17a) without showing other constituent elements.

In step S11, as shown in FIG. 4A, the control unit 18 controls the substrate stage 11 to arrange the substrate W below the dispenser 15. In step S12, the control unit 18 controls the supply unit 17 to supply a filling promotion gas to between the mold M and the substrate W. The control unit 18 may perform step S12 simultaneously with or before step S11. In step S13, as shown in FIG. 4B, the control unit 18 controls the dispenser 15 to dispense the imprint material R to each of a plurality of shot regions on the substrate W while controlling the substrate stage 11 to relatively move the substrate W and the dispenser 15 in the X and Y directions. In step S14, the control unit 18 determines whether the imprint material R has been dispensed to all the plurality of shot regions on the substrate W. If there is any shot region on which the imprint material R has not been dispensed, the process returns to step S13 to dispense to the imprint material R to the shot region. In contrast to this, if there is no shot region to which the imprint material R has not been dispensed (the imprint material R has been dispensed to all the shot regions), the process advances to step S15.

In step S15, the control unit 18 drives the substrate stage 11 to arrange a shot region subjected to an imprint process (to be referred to as a target region hereinafter) of a plurality of shot regions on the substrate W to below the pattern portion 31a of the mold M. In step S16, the control unit 18 controls the deformation unit 13 to deform the mold M (first surface 31 and pattern portion 31a) into a convex shape. In step S17, as shown in FIG. 4C, the control unit 18 controls the imprint head 12 to reduce the spacing between the mold M and the substrate W, and brings the mold M into contact with the imprint material R on a target shot region (contact step). At this time, the control unit 18 preferably controls the deformation of the mold M in accordance with the contact area between the mold M and the imprint material R. For example, the control unit 18 controls the deformation unit 13 to gradually reduce the internal pressure of the cavity 32b as the contact region between the mold M and the imprint material R increases after the mold M (for example, a central portion of the pattern portion 31a) begins to come into contact with the imprint material R. This can form the pattern portion 31a into a planar shape when the entire pattern portion 31a comes into contact with the imprint material R.

In step S18, the control unit 18 controls the supply unit 17 to stop supplying the filling promotion gas, and leaves the mold M and the imprint material R in a contact state for a predetermined time. The predetermined time is the time (filling time) for filling the concave-convex pattern (concave portions) of the pattern portion 31a with the imprint material R, and can be set in advance. In step S19, the control unit 18 controls the curing unit 14 to irradiate the imprint material R with light while the mold M is in contact with the imprint material R, thereby curing the imprint material R (curing step). In step S20, the control unit 18 controls the imprint head 12 to increase the spacing between the mold M and the substrate W, and separates the cured imprint material R from the mold M (releasing step), as shown in FIG. 4D. This can form a pattern with a three-dimensional shape conforming to the pattern of the mold M on the imprint material R on the target shot region.

In step S21, the control unit 18 determines whether an imprint process has been performed for all the plurality of shot regions on the substrate W. If there is no shot region (unprocessed shot region) for which an imprint process has not been performed, the processing is terminated. In contrast, if there is any unprocessed shot region, the process advances to step S22. In step S22, the control unit 18 controls the supply unit 17 to supply a filling promotion gas to between the mold M and the substrate W. The process then returns to step S15 to set the unprocessed shot region as a target shot region and perform an imprint process, as shown in FIG. 4E.

In this case, in the flowchart shown in FIG. 3, after the contact step in step S17, the supply of the filling promotion gas is stopped and resumed after the releasing step in step S20. However, this is not exhaustive. For example, the supply of the filling promotion gas may be stopped before the contact step in step S17 and resumed before or during the curing step S19. In addition, the supply of the filling promotion gas may be always performed without being stopped.

[Arrangement of Mold]

As described above, the imprint apparatus 100 according to this embodiment is configured to continuously dispense the imprint material R onto each of a plurality of shot regions on the substrate W and then continuously perform an imprint process for each of the plurality of shot regions. Such a method is advantageous in improving throughput. However, because a filling promotion gas is supplied while the substrate W is arranged below the mold M, it can be difficult to efficiently make the filling promotion gas flow into the narrow space S between the pattern portion 31a of the mold M and the substrate W. In addition, when the mold M is brought into contact with the imprint material R, the spacing between the mold M and the substrate W decreases, and the filling promotion gas leaks from between the mold M and the substrate W. For this reason, as an imprint process is repeated, the concentration of the filling promotion gas in the space S can decrease at the time of an imprint process.

The mold M according to this embodiment has a concave portion 31b provided in a peripheral portion (surrounding portion) of the pattern portion 31a on the first surface 31 so as not to penetrate to second surface 32. As described above, providing the concave portion 31b in the first surface 31 makes it possible to make a filling promotion gas existing in the space S between the pattern portion 31a and the substrate W flow into the concave portion 31b and temporarily retain the gas when the mold M comes into contact with the imprint material R. In addition, when the spacing between the mold M and the substrate W is increased to separate the mold M from the cured imprint material R, the filling promotion gas in the concave portion 31b can be made to flow into the space S. Using the mold M having the concave portion 31b provided in the first surface 31 in this manner can reduce a reduction in the concentration of the filling promotion gas in the space S at the time of an imprint process.

In this case, the volume of the concave portion 31b provided in the first surface 31 of the mold M is preferably larger than the maximum volume of the space S formed between the pattern portion 31a and the substrate W in an imprint process. Configuring the mold M in this manner can make all the filling promotion gas in the space S flow into the concave portion 31b. This can further efficiently reduce a reduction in the concentration of the filling promotion gas.

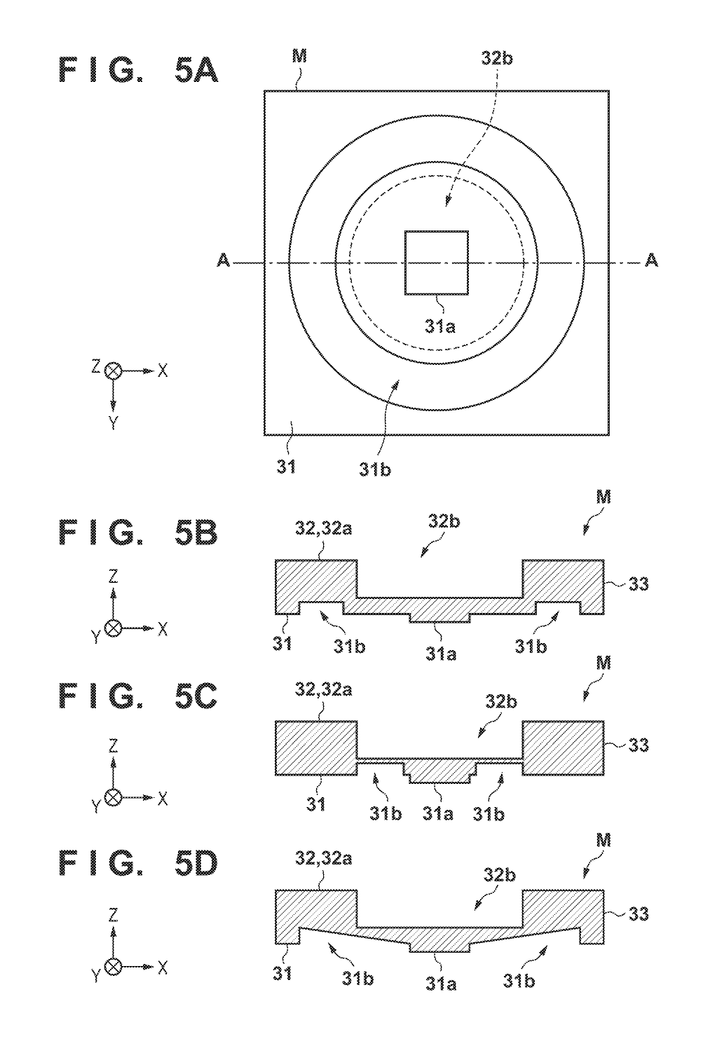

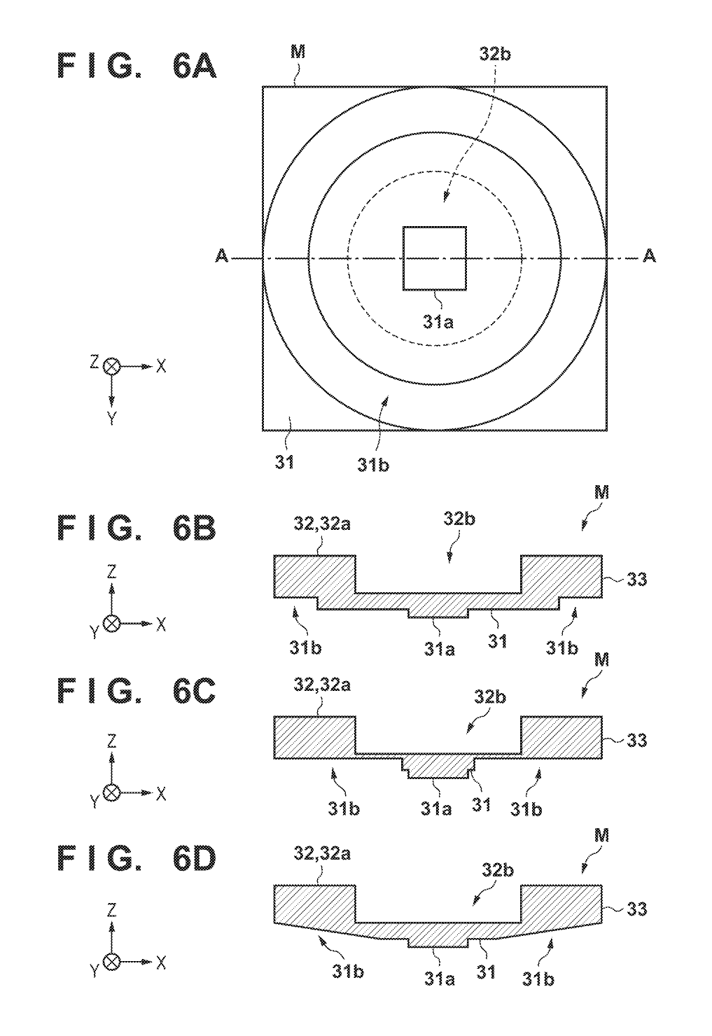

An example of the arrangement of the mold M having the concave portion 31b provided in the first surface 31 will be described below with reference to FIGS. 5A to 5D and 6A to 6D. FIGS. 5A to 5D and 6A to 6D are views showing an example of the arrangement of the mold M according to this embodiment. FIGS. 5A to 6A each are a view of the mold M when seen from the substrate side. FIGS. 5B and 6B each are a sectional view taken along line A-A. FIGS. 5C, 5D, 6C, and 6D each are a modification of the mold M. In this case, the phrase “seen from the substrate side” means “in planar view with respect to the second surface 32 (held portion 32a) of the mold M” or “in directions (X and Y directions) parallel to the second surface 32 (held portion 32a) of the mold M”. In addition, a side surface 33 of the mold M can be defined as a surface connecting the first surface 31 of the mold M to the second surface 32.

FIGS. 5A to 5D show the mold M having the concave portion 31b provided in the first surface 31 so as to surround the pattern portion 31a. The mold M shown in FIGS. 5A and 5B is configured such that the concave portion 31b provided in the first surface 31 does not overlap the cavity 32b provided in the second surface 32 when viewed from the substrate side. That is, in the case shown in FIGS. 5A and 5B, the concave portion 31b is provided in a portion of the first surface 31 which is located on the opposite side to the held portion 32a of the second surface 32 (a portion of the first surface 31 which overlaps the cavity 32b when viewed from the substrate side).

The mold M shown in FIG. 5C is configured such that the concave portion 31b provided in the first surface 31 includes a portion overlapping the cavity 32b provided in the second surface 32 when viewed from the substrate side. In the case shown in FIG. 5C, the entire concave portion 31b provided in the first surface 31 overlaps the cavity 32b when viewed from the substrate side. In addition, the concave portion 31b is preferably provided in the first surface 31 so as to be separated from the pattern portion 31a without coming into contact with the pattern portion 31a from the viewpoint of the strength of the mold M (pattern portion 31a).

The mold M shown in FIG. 5D is configured such that the depth of the concave portion 31b increases with an increase in distance from the pattern portion 31a, that is, the bottom surface of the concave portion 31b is inclined. The mold M having such an arrangement can more efficiently make a filling promotion gas flow from the space S into the concave portion 31b and the filling promotion gas flow from the concave portion 31b into the space S.

FIG. 7 is a view showing specific examples of the dimensions of the mold M shown in FIG. 5A in the same reduced scale in the X, Y, and Z directions. The overall dimensions of the mold M are a=150 mm and b=150 mm. A thickness h of the mold M is 6.35 mm. The dimensions of the pattern portion 31a are c=26 mm and d=33 mm. The cavity 32b has a circular shape with a radius e of 32 mm. In this case, assuming that a maximum gap f that can be formed between the pattern portion 31a and the substrate W is 0.5 mm, it is possible to obtain an inner diameter Pin, an outer diameter Pout, and a depth D of the doughnut-shaped concave portion 31b having a volume larger than the maximum volume of the space S between pattern portion 31a and the substrate W For example, when inner diameter Pin=35 mm and outer diameter Pout=70 mm, setting the depth D to 0.17 mm or more can make the volume of the concave portion 31b larger than the maximum volume of the space S. In addition, when inner diameter Pin=35 mm and outer diameter Pout=45 mm, setting the depth D to 0.77 mm or more can make the volume of the concave portion 31b larger than the maximum volume of the space S. In this case, the depth D of the concave portion 31b is preferably smaller than the thickness of a portion in which the cavity 32b is provided from the viewpoint of the strength of the mold M.

FIGS. 6A to 6D show the mold M having the concave portion 31b provided in the first surface 31 so as to surround the pattern portion 31a and communicate with the side surface 33 of the mold M. The mold M shown in FIGS. 6A and 6B is configured such that the concave portion 31b provided in the first surface 31 does not overlap the cavity 32b provided in the second surface 32 when viewed from the substrate side. The mold M shown in FIG. 6C is configured such that the concave portion 31b provided in the first surface 31 includes a portion overlapping the cavity 32b provided in the second surface 32 when viewed from the substrate side. The mold M shown in FIG. 6D is configured such that the depth of the concave portion 31b gradually increases with an increase in distance from the pattern portion 31a.

As described above, the mold M according to this embodiment has the concave portion 31b provided in a portion of the first surface 31 which is located around the pattern portion 31a. Performing an imprint process by using the mold M having the concave portion 31b provided in the first surface 31 in this manner makes it possible to temporarily retain, in the concave portion 31b, the filling promotion gas in the space S between the pattern portion 31a of the mold M and the substrate W at the time of a contact step. Even if, therefore, an imprint process is to be continuously performed for a plurality of shot regions on the substrate W, it is possible to reduce a reduction in the concentration of the filling promotion gas in the space S.

<Second Embodiment>

The second embodiment according to the present invention will be described. In a method of continuously dispensing an imprint material R for each of a plurality of shot regions on a substrate W, blowing out a filling promotion gas from a blowing-out port 17a can cause volatilization, shape change, positional shift, and the like of the imprint material R on other shot regions. A mold M is preferably configured such that a filling promotion gas blown out from the blowing-out port 17a can efficiently flow between a mold M and the substrate W. The mold M according to the second embodiment has a flow channel 31c provided in a first surface 31 so as to make a concave portion 31b of the first surface 31 communicate with a side surface 33 of the mold M.

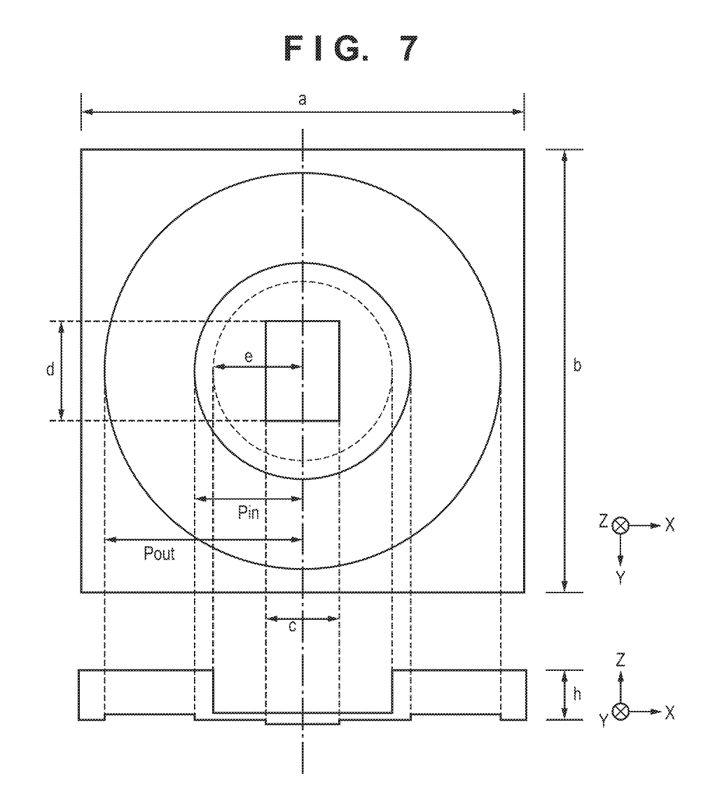

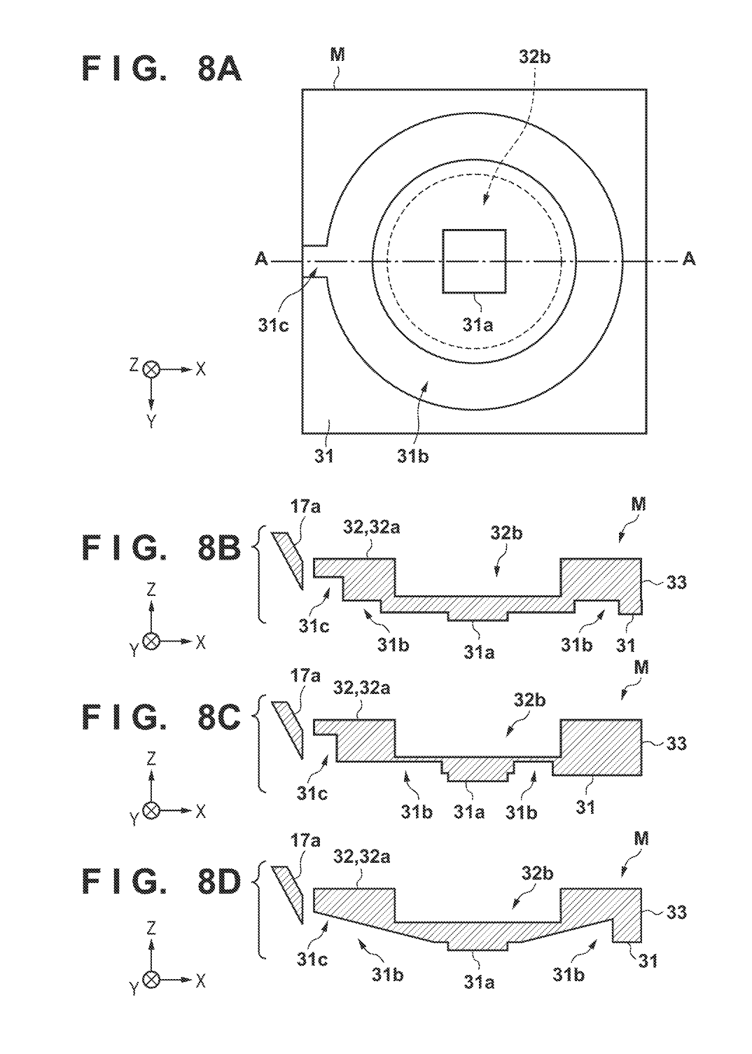

FIG. 8A to 8D show the mold M having the flow channel 31c provided in the first surface 31 so as to make the concave portion 31b in the first surface 31 communicate with the side surface 33 of the mold M. FIG. 8A is a view showing the mold M when viewed from the substrate side. FIG. 8B is a sectional view taken along line A-A. FIGS. 8C and 8B each show a modification of the mold M. The mold M shown in FIGS. 8A and 8B is configured such that the concave portion 31b provided in the first surface 31 does not overlap a cavity 32b provided in a second surface 32 when viewed from the substrate side. The mold M shown in FIG. 8C is configured such that the concave portion 31b provided in the first surface 31 includes a portion overlapping the cavity 32b provided in the second surface 32 when viewed from the substrate side. The mold M shown in FIG. 8D is configured such that the depth of the concave portion 31b gradually increases with an increase in distance from a pattern portion 31a.

The flow channel 31c is, for example, a groove provided in the first surface 31 so as to connect the concave portion 31b of the first surface 31 to the side surface 33 of the mold M. The flow channel 31c is provided in the first surface 31 to facilitate supplying the gas blown out from the blowing-out port 17a into the concave portion 31b via the flow channel 31c when a mold holding unit 12a holds the mold M. That is, the flow channel 31c can be provided at a position of the side surface 33 of the mold M which faces the blowing-out port 17a. In the mold M configured in this manner, the blowing-out port 17a may be configured to blow out a filling promotion gas toward the side surface 33 of the mold M instead of being configured to blow out a filling promotion gas to between the mold M and the substrate W. In this case, the number of flow channels 31c is not limited to one, and flow channels 31c may be provided in two or more side surfaces 33 of the mold M.

As described above, the mold M according to this embodiment is provided with the flow channel 31c to make the concave portion 31b of the first surface 31 communicate with the side surface 33 of the mold M. This makes it possible to reduce a reduction in the concentration of a filling promotion gas at the time of an imprint process and efficiently supply the filling promotion gas to the concave portion 31b of the first surface 31 as in the first embodiment. In addition, when a plurality of blowing-out ports 17a are provided, blowing out a filling promotion gas from only the blowing-out port 17a, of the blowing-out ports 17a, which faces the flow channel 31c can reduce the influence on the imprint material R on other shot regions.

<Third Embodiment>

The third embodiment of the present invention will be described. When a target shot region subjected to an imprint process is located on a peripheral edge portion of a substrate W, a mold M sometimes partly protrudes from the substrate W in the X and Y directions. FIGS. 9A and 9B are views showing the positional relationship between the mold M and the substrate W in the X and Y directions. FIG. 9A and 9B show four blowing-out ports 17a respectively provided in four side surfaces 33 of the mold M. FIG. 9A shows the positional relationship between the mold M and the substrate W when a target shot region is located in a central portion of the substrate W. FIG. 9B shows the positional relationship between the mold M and the substrate W when a target shot region is located on a peripheral edge portion of the substrate W. Referring to FIGS. 9A and 9B, the substrate W has a diameter of 300 mm. One side of the mold M has a length of 150 mm. The blowing-out port 17a is spaced away from the mold M by 80 mm.

As shown in FIG. 9A, when a target shot region is located on a central portion of the substrate W, the entire mold M overlaps the substrate W in the X and Y directions. For this reason, as shown in FIGS. 5A to 5D and 6A to 6D, it is possible to use a mold having a concave portion 31b provided in the first surface so as to surround a pattern portion 31a. As shown in FIG. 9B, when a target shot region is located on a peripheral edge portion of the substrate W, the mold M partly protrudes from the substrate W in the X and Y directions. Although a flush face plate 21 is provided around the substrate W, the upper surface of the flush face plate 21 can be adjusted to be lower than the upper surface of the substrate W by about 0.1 mm due to tolerances and the like at the time of assembly to form a gap of about 0.1 mm between the substrate W and the flush face plate 21. For this reason, using any of the molds M shown in FIGS. 5A to 5D and 6A to 6D will make a filling promotion gas flow out from a portion of the mold M which does not overlap the substrate W. Accordingly, the mold M according to this embodiment has a concave portion 31b provided in a first surface 31 so as to be asymmetrical with respect to the pattern portion 31a.

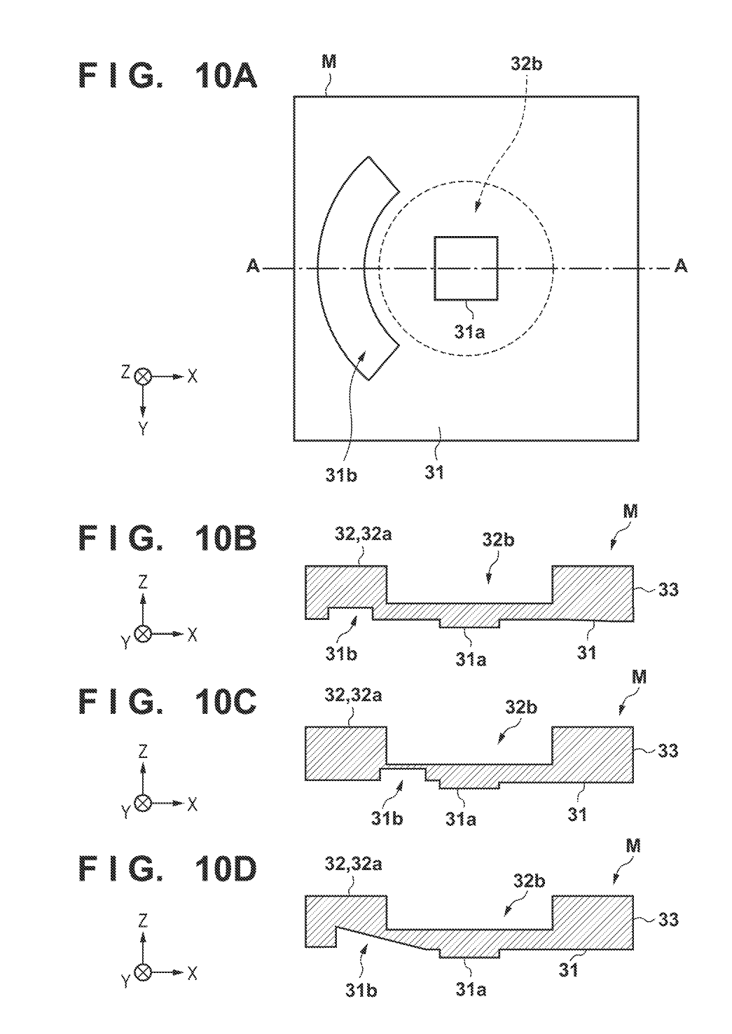

FIGS. 10A to 10D, 11A to 11D, and 12A to 12D are views each showing an example of the arrangement of the mold M according to this embodiment. FIGS. 10A, 11A, and 12A each are a view of the mold M when viewed from the substrate side. FIGS. 10B, 11B, and 12B each are a sectional view taken along line A. FIGS. 10C, 10D, 11C, 11D, 12C, and 12D each show a modification of the mold M. The concave portion 31b of the M is provided in a portion, of the first surface 31 of the mold M, which overlaps the substrate W in the X and Y directions. A plurality of such molds M can be manufactured by changing the positions and ranges of the concave portions 31b in the molds in accordance with the positions of target shot regions on substrates. These molds can be selectively used in accordance with the positions of target shot regions on a substrate.

FIGS. 10A to 10D each show the mold M having the concave portion 31b provided in the first surface 31 so as to be asymmetrical with respect to the pattern portion 31a. The mold M shown in FIGS. 10A and 10B is configured such that the concave portion 31b provided in the first surface 31 does not overlap a cavity 32b provided in the second surface 32 when viewed from the substrate side. The mold M shown in FIG. 10C is configured such that the concave portion 31b provided in the first surface 31 includes a portion overlapping the cavity 32b provided in a second surface 32 when viewed from the substrate side. The mold M shown in FIG. 10D is configured such that the depth of the concave portion 31b gradually increases with an increase in distance from the pattern portion 31a.

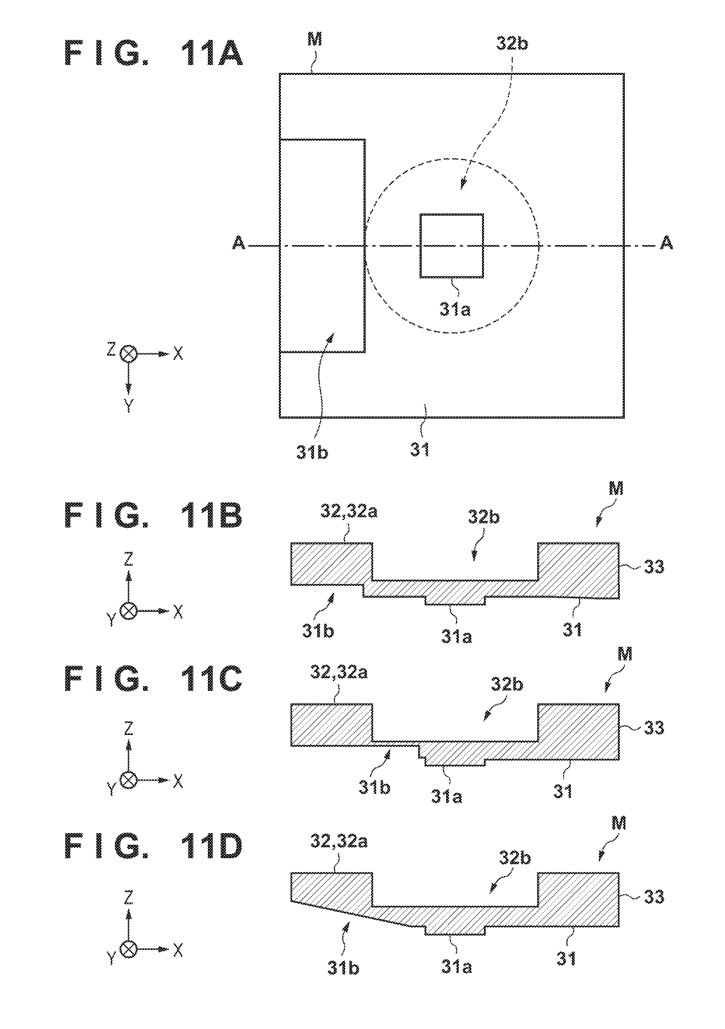

FIGS. 11A to 11D each show the mold M having the concave portion 31b provided in the first surface 31 so as to be asymmetrical with respect to the pattern portion 31a and communicate with the side surface 33 of the mold M. The mold M shown in FIGS. 11A and 11B is configured such that the concave portion 31b provided in the first surface 31 does not overlap the cavity 32b provided in the second surface 32 when viewed from the substrate side. The mold M shown in FIG. 11C is configured such that the concave portion 31b provided in the first surface 31 includes a portion overlapping the cavity 32b provided in the second surface 32 when viewed from the substrate side. The mold M shown in FIG. 11D is configured such that the depth of the concave portion 31b gradually increases with an increase in distance from the pattern portion 31a.

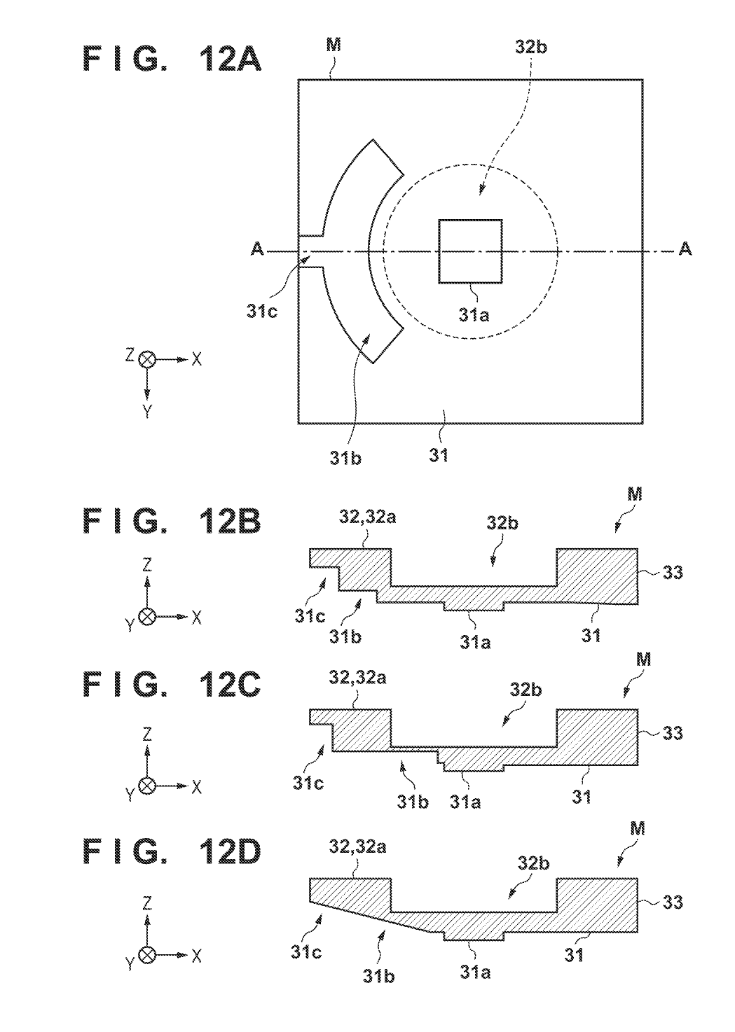

FIGS. 12A to 12D each show the mold M further having a flow channel 31c provided in the first surface 31 so as to make the concave portion 31b of the first surface 31 communicate with the side surface 33 of the mold M. The mold M shown in FIGS. 12A and 12B is configured such that the concave portion 31b provided in the first surface 31 does not overlap the cavity 32b provided in the second surface 32 when viewed from the substrate side. The mold M shown in FIG. 12C is configured such that the concave portion 31b provided in the first surface 31 includes a portion overlapping the cavity 32b provided in the second surface 32 when viewed from the substrate side. In addition, the mold M shown in FIG. 12D is configured such that the depth of the concave portion 31b gradually increases with an increase in distance from the pattern portion 31a.

<Embodiment of Method of Manufacturing Article>

A method of manufacturing an article according to an embodiment of the present invention is suitable for manufacturing an article, for example, a microdevice such as a semiconductor device or an element having a microstructure. The method of manufacturing the article according to this embodiment includes a step of forming a pattern on an imprint material supplied (dispensed) onto a substrate using the above-described imprint apparatus (imprint method), and a step of processing the substrate on which the pattern is formed in the preceding step. This manufacturing method further includes other known steps (oxidation, deposition, vapor deposition, doping, planarization, etching, resist separation, dicing, bonding, packaging, and the like). The method of manufacturing the article according to this embodiment is advantageous in at least one of the performance, the quality, the productivity, and the production cost of the article, as compared to a conventional method.

The pattern of a cured product formed using the imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

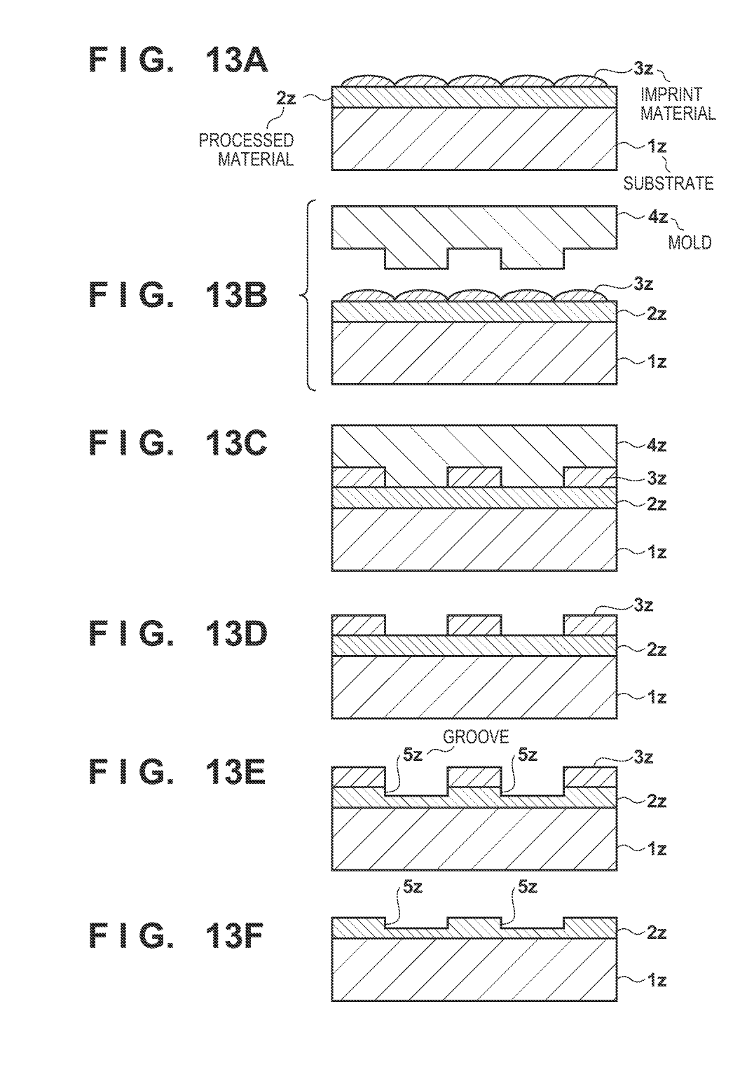

A detailed method of manufacturing an article will be described next. As shown in FIG. 13A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 13B, a side of a mold 4z for imprint with an uneven pattern is directed to and caused to face the imprint material 3z on the substrate. As shown in FIG. 13C, the substrate 1z to which the imprint material 3z is applied is brought into contact with the mold 4z, and a pressure is applied. The gap between the mold 4z and the processed material 2z is filled with the imprint material 3z. In this state, when the imprint material 3z is irradiated with enemy for curing through the mold 4z, the imprint material 3z is cured.

As shown in FIG. 13D, after the imprint material 3z is cured, the mold 4z is separated from the substrate 1z. Then, the pattern of the cured product of the imprint material 3z is formed on the substrate 1z. In the pattern of the cured product, the concave portion of the mold corresponds to the convex portion of the cured product, and the concave portion of the mold corresponds to the convex portion of the cured product. That is, the uneven pattern of the mold 4z is transferred to the imprint material 3z.

As shown in FIG. 13E, when etching is performed using the pattern of the cured product as an etching resistant mask, a portion of the surface of the processed material 2z where the cured product does not exist or remains thin is removed to form a groove 5z. As shown in FIG. 13F, when the pattern of the cured product is removed, an article with the grooves 5z formed in the surface of the processed material 2z can be obtained. Here, the pattern of the cured product is removed. However, instead of processing or removing the pattern of the cured product, it may be used as, for example, an interlayer dielectric film included in a semiconductor element or the like, that is, a constituent member of an article.

<Other Embodiments>

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-045925 filed on Mar. 13, 2018, which is hereby incorporated by reference herein in its entirety.

What is claimed is:

1. A mold having a concave-convex pattern, the pattern being transferred onto an imprint material on a substrate by an imprint apparatus, the mold comprising:
a first surface having a pattern portion on which the pattern; and
a second surface located on an opposite side to the first surface,
wherein a concave portion that does not penetrate to the second surface is provided in the first surface so as to be spaced apart from the pattern portion.

2. The mold according to claim 1, wherein a volume of the concave portion is larger than a maximum volume of a space formed between the pattern portion and the substrate in a process of transferring the pattern onto the imprint material by the imprint apparatus.

3. The mold according to claim 1, wherein the second surface is provided with a second concave portion on an opposite side to a region of the first surface which includes the pattern portion.

4. The mold according to claim 3, wherein the concave portion is provided in the first surface so as not to overlap the second concave portion when viewed from a direction perpendicular to the first surface.

5. The mold according to claim 3, wherein the concave portion is provided in the first surface so as to include a portion overlapping the second concave portion when viewed from a direction perpendicular to the first surface.

6. The mold according to claim 1, wherein the mold has a side surface connecting the first surface to the second surface, the first surface being provided with a flow channel making the concave portion communicate with the side surface.

7. The mold according to claim 6, wherein the imprint apparatus includes a holding unit configured to hold the mold, and a blowing-out port configured to blow out a gas to between the mold and the substrate, and
the flow channel is provided at a position to face the blowing-out port so that a gas blown out from the blowing-out port is supplied to the concave portion via the flow channel in a state where the mold is held by the holding unit.

8. The mold according to claim 1, wherein
the mold has a side surface connecting the first surface to the second surface, and
the concave portion is provided in the first surface so as to communicate with the side surface.

9. The mold according to claim 1, wherein the concave portion is provided in the first surface so as to increase in depth with an increase in distance from the pattern portion.

10. The mold according to claim 1, wherein the concave portion is provided in the first surface so as to surround the pattern portion.

11. The mold according to claim 1, wherein the concave portion is provided in the first surface so as to be asymmetrical with respect to the pattern portion.

12. The mold according to claim 1, wherein the pattern portion has a shape protruding from the first surface.

13. A mold having a concave-convex pattern, the pattern being transferred onto an imprint material on a substrate by an imprint apparatus, the mold comprising:
a first surface having a pattern portion on which the pattern is formed and a peripheral portion which surrounds the pattern portion; and
a second surface located on an opposite side to the first surface so as to be parallel to the first surface,
wherein a concave portion having a depth smaller than a distance between the first surface and the second surface is provided in the peripheral portion of the first surface so as to be spaced apart from the pattern portion.

14. The mold according to claim 13, wherein the concave portion has an annular shape when viewed from a direction perpendicular to the first surface.

15. The mold according to claim 13, wherein a volume of the concave portion is larger than a maximum volume of a space formed between the pattern portion and the substrate in a process of transferring the pattern onto the imprint material by the imprint apparatus.

16. The mold according to claim 13, wherein the second surface is provided with a second concave portion on an opposite side to a region of the first surface which includes the pattern portion, and the concave portion is provided in the first surface so as not to overlap the second concave portion when viewed from a direction perpendicular to the first surface.

17. The mold according to claim 13, wherein the second surface is provided with a second concave portion on an opposite side to a region of the first surface which includes the pattern portion, and the concave portion is provided in the first surface so as to include a portion overlapping the second concave portion when viewed from a direction perpendicular to the first surface.

18. The mold according to claim 13, wherein the mold has a side surface connecting the first surface to the second surface, and the first surface is provided with a flow channel making the concave portion communicate with the side surface.

19. The mold according to claim 18, wherein
the imprint apparatus includes a holding unit configured to hold the mold, and a blowing-out port configured to blow out a gas to between the mold and the substrate, and
the flow channel is provided at a position facing the blowing-out port so that a gas blown out from the blowing-out port is supplied to the concave portion via the flow channel in a state where the mold is held by the holding unit.

20. An imprint apparatus that forms a pattern of an imprint material onto a substrate by using a mold, the apparatus comprising a mold holding unit configured to hold the mold,
wherein the mold has a concave-convex pattern, the pattern being transferred onto an imprint material on a substrate by an imprint apparatus, the mold comprising:
a first surface having a pattern portion on which the pattern; and
a second surface located on an opposite side to the first surface,
wherein a concave portion that does not penetrate to the second surface is provided in the first surface so as to be spaced apart from the pattern portion.

21. An imprint apparatus that forms a pattern of an imprint material onto a substrate by using a mold, the apparatus comprising a mold holding unit configured to hold the mold,
wherein the mold has a concave-convex pattern, the pattern being transferred onto an imprint material on a substrate by an imprint apparatus, the mold comprising:
a first surface having a pattern portion on which the pattern is formed and a peripheral portion which surrounds the pattern portion; and
a second surface located on an opposite side to the first surface so as to be parallel to the first surface,
wherein a concave portion having a depth smaller than a distance between the first surface and the second surface is provided in the peripheral portion of the first surface so as to be spaced apart from the pattern portion.

22. A method of manufacturing an article, the method comprising:
forming a pattern on a substrate using an imprint apparatus;
processing the substrate, on which the pattern has been formed, to manufacture the article,
wherein the imprint apparatus that forms a pattern of an imprint material onto a substrate by using a mold, the apparatus comprising a mold holding unit configured to hold the mold,
wherein the mold has a concave-convex pattern, the pattern being transferred onto an imprint material on a substrate by an imprint apparatus, the mold comprising:
a first surface having a pattern portion on which the pattern; and
a second surface located on an opposite side to the first surface,
wherein a concave portion that does not penetrate to the second surface is provided in the first surface so as to be spaced apart from the pattern portion.
